(19) United States
(12) Patent Application Publication
(10) Pub. No.: US 2026/0005697 A1
(43) Pub. Date: Jan. 1, 2026

(54) AVERAGING A DIGITAL PHASE LOCKED LOOP OUTPUT FREQUENCY TO CALCULATE A PRESET VALUE FOR USE IN THE EVENT OF A LINK LOSS

(71) Applicant: Microsemi SOC Corp., Chandler, AZ (US)

(72) Inventors: Peter Stinson, Wind Gap, PA (US); Pinninti Arjun, Hyderabad (IN)

(73) Assignee: Microsemi SOC Corp., Chandler, AZ (US)

(21) Appl. No.: 18/895,490

(22) Filed: Sep. 25, 2024

(30) Foreign Application Priority Data
Jul. 1, 2024 (IN) 202411050392

(51) Int. Cl. H03L 7/197; H03L 7/091

(52) U.S. Cl. CPC H03L 7/1974; H03L 7/091

(57) ABSTRACT

Systems and methods for averaging a digital phase locked loop output frequency to calculate a preset value for use in the event of a link loss are disclosed. The method may include reading a fractional portion of an output of a digital phase locked loop (DPLL), calculating an integer portion of the output of the DPLL, and accumulating a predetermined number of samples of the fractional portion and the integer portion of the output of the DPLL. The method may include computing an average value of an output frequency of the DPLL over the predetermined number of samples, extracting a fractional portion and an integer portion of the average value of the output frequency of the DPLL, and loading the fractional portion and the integer portion of the average value of the output frequency of the DPLL as preset values in a fractional-N phase locked loop.

### PRIORITY

This application claims priority to Indian Provisional Patent Application No. 202411050392 filed Jul. 1, 2024, the contents of which are hereby incorporated in their entirety.

### TECHNICAL FIELD

The present disclosure relates to meeting the holdover specifications of the Synchronous Ethernet standard (G.8262), and, in particular, to averaging a digital phase locked loop output frequency to calculate a preset value for use in the event of a link loss.

### BACKGROUND

SyncE, short for Synchronous Ethernet, is an International Telecommunication Union Telecommunication Standardization Sector (ITU-T) standard for ensuring precise timing in Ethernet networks. SyncE distributes a timing signal across the physical layer of the network. This signal acts as a reference point for all devices, synchronizing the devices. SyncE is less susceptible to delays that can occur at higher data layers. SyncE may be used for applications like mobile networks and financial trading, where even slight timing discrepancies can cause issues.

SyncE holdover is a feature of SyncE that allows the network to maintain a temporary source of synchronization when the main SyncE timing signal is unavailable. The SyncE specification defines the parts per million (ppm) holdover tolerance values to be within +/−4.6 ppm, i.e., maintaining the transmit clock within +/−4.6 ppm of the recovered clock to be SyncE compliant.

### SUMMARY OF THE INVENTION

Aspects provide systems and methods for averaging a digital phase locked loop output frequency to calculate a preset value for use in the event of a link loss is disclosed. Examples of the present disclosure may include a method. The method may include reading a fractional portion of an output of a digital phase locked loop (DPLL). The method may also include calculating an integer portion of the output of the DPLL. The method may additionally include accumulating a predetermined number of samples of the fractional portion and the integer portion of the output of the DPLL. The method may include computing an average value of an output frequency of the DPLL over the predetermined number of samples. The method may also include extracting a fractional portion and an integer portion of the average value of the output frequency of the DPLL. The method may further include loading the fractional portion and the integer portion of the average value of the output frequency of the DPLL as preset values in a fractional-N phase locked loop (PLL).

In combination with any of the above examples, the method may also include calculating a sample of the output of the DPLL. The method may additionally include computing the average value of the output frequency of the DPLL using the sample the output of the DPLL.

In combination with any of the above examples, the predetermined number of samples may be based on an operating frequency of the DPLL.

In combination with any of the above examples, the method may include monitoring a frequency of an input clock. The method may also include identifying a loss of a link to the input clock. The method may further include generating a link loss signal.

In combination with any of the above examples, the method may include outputting a clock signal based on the preset values in the fractional-N PLL.

In combination with any of the above examples, the method may include reading the fractional portion of the output of the DPLL at a predetermined interval.

In combination with any of the above examples, the predetermined number of samples may be accumulated on a rolling basis.

Alone or in combination with any of the above examples, examples of the present disclosure may include an apparatus. The apparatus may include a digital phase locked loop (DPLL) circuit. The apparatus may also include a fractional-N phase locked loop (PLL) circuit. The apparatus may further include a control circuit. The control circuit may be to read a fractional portion of an output of the DPLL circuit. The control circuit may also be to calculate an integer portion of the output of the DPLL circuit. Additionally, he control circuit may be to accumulate a predetermined number of samples of the fractional portion and the integer portion of the output of the DPLL circuit. The control circuit may be to compute an average value of an output frequency of the DPLL circuit over the predetermined number of samples. The control circuit may also be to extract a fractional portion and an integer portion of the average value of the output frequency of the DPLL circuit. Further, The control circuit may be to load the fractional portion and the integer portion of the average value of the output frequency of the DPLL circuit as preset values in the fractional-N PLL circuit.

In combination with any of the above examples, the control circuit may be to calculate a sample of the output of the DPLL. The control circuit may also be to compute the average value of the output frequency of the DPLL using the sample of the output of the DPLL.

In combination with any of the above examples, the predetermined number of samples may be based on an operating frequency of the DPLL.

In combination with any of the above examples, the control circuit may be to monitor a frequency of an input clock. The control circuit may also be to identify a loss of a link to the input clock. The control circuit may additionally be to generate a link loss signal.

In combination with any of the above examples, the control circuit may be to output a clock signal based on the preset values in the fractional-N PLL.

In combination with any of the above examples, the control circuit may be to read the fractional portion of the output of the DPLL at a predetermined interval.

1 In combination with any of the above examples, the predetermined number of samples may be accumulated on a rolling basis.

Alone or in combination with any of the above examples, examples of the present disclosure may include an article of manufacture. The article of manufacture may include a non-transitory memory including machine-readable instructions. The machine-readable instruction may, when executed by a processor, cause the processor to read a fractional portion of an output of a digital phase locked loop (DPLL). The machine-readable instruction may also cause the processor to calculate an integer portion of the output of the DPLL. Additionally, the machine-readable instruction may also cause the processor to accumulate a predetermined number of samples of the fractional portion and the integer portion of the output of the DPLL. The machine-readable instruction may also cause the processor to compute an average value of an output frequency of the DPLL over the predetermined number of samples. The machine-readable instruction may cause the processor to extract a fractional portion and an integer portion of the average value of the output frequency of the DPLL. Further, the machine-readable instruction may cause the processor to load the fractional portion and the integer portion of the average value of the output frequency of the DPLL as preset values in a fractional-N phase locked loop (PLL).

In combination with any of the above examples, the machine-readable instructions further cause the processor to calculate a sample of the output of the DPLL. The machine-readable instruction may cause the processor to compute the average value of the output frequency of the PLL using the sample of the output of the DPLL.

In combination with any of the above examples, the predetermined number of samples may be based on an operating frequency of the DPLL.

In combination with any of the above examples, the machine-readable instructions may further cause the processor to monitor a frequency of an input clock. The machine-readable instruction may also cause the processor to identify a loss of a link to the input clock. Further, the machine-readable instruction may cause the processor to generate a link loss signal.

In combination with any of the above examples, the machine-readable instructions may further cause the processor to output a clock signal based on the preset values in the fractional-N PLL.

In combination with any of the above examples, the machine-readable instructions may further cause the processor to read the fractional portion of the output of the DPLL at a predetermined interval.

### BRIEF DESCRIPTION OF THE DRAWINGS

The figures illustrate examples of systems and methods for averaging a digital phase locked loop output frequency to calculate a preset value for use in the event of a link loss.

FIG. 1 is a block diagram of a system for averaging a digital phase locked loop output frequency to calculate a preset value for use in the event of a link loss, according to examples of the present disclosure;

FIG. 2 illustrates a method for averaging a digital phase locked loop output frequency to calculate a preset value for use in the event of a link loss, according to examples of the present disclosure; and

FIG. 3 illustrates a more detailed method for averaging a digital phase locked loop output frequency to calculate a preset value for use in the event of a link loss, according to examples of the present disclosure.

The reference number for any illustrated element that appears in multiple different figures has the same meaning across the multiple figures, and the mention or discussion herein of any illustrated element in the context of any particular figure also applies to each other figure, if any, in which that same illustrated element is shown.

### DESCRIPTION

According to an aspect of the invention, averaging a digital phase locked loop output frequency to calculate a preset value for use in the event of a link loss is provided. The averaging algorithm may provide a lightweight method for achieving the short-and long-term holdover specifications of the SyncE standard. Specifically, the holdover specifications of the SyncE standard specify frequency matching within 0.05 parts per million (ppm). Some systems and methods for meeting the holdover specifications use external devices to perform the switchover in the event that the link to a timing signal is lost. The disclosed system and methods may use programmable components in a field programmable gate array (FPGA) architecture without using an external device, which may reduce the cost associated with SyncE frequency tracking and holdover specifications.

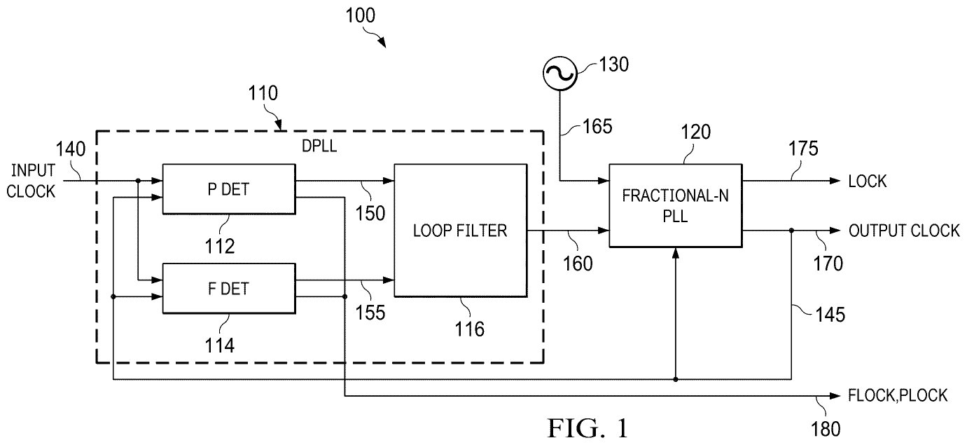

FIG. 1 is a block diagram of a system for averaging a digital phase locked loop output frequency to calculate a preset value for use in the event of a link loss, according to examples of the present disclosure. System 100 may be a field programmable gate array (FPGA), application specific integrated circuit (ASIC), application specific standard product (ASSP), or any other suitable device. System 100 may include digital phase locked loop (DPLL) 110 and fractional-N phase locked loop (PLL) 120.

DPLL 110 may include phase detection circuit 112, frequency detection circuit 114, and loop filter circuit 116. DPLL may receive input clock signal 140 at phase detection circuit 112 and frequency detection circuit 114. Input clock signal 140 may be a reference clock signal or timing signal used in the Synchronous Ethernet standard (G.8262).

Phase detection circuit 112 may compare the phase difference between input clock signal 140 and feedback signal 145 from the output of fractional-N PLL 120. Phase error signal 150 of phase detection circuit 112 may be an error signal proportional to the phase difference between input clock signal 140 and feedback signal 145. Phase detection circuit 112 may output phase error signal 150 to loop filter circuit 116.

Frequency detection circuit 114 may compare the frequency difference between input clock signal 140 and feedback signal 145 from the output of fractional-N PLL 120. Frequency error signal 155 of frequency detection circuit 114 may be an error signal proportional to the frequency difference between input clock signal 140 and feedback signal 145. Frequency detection circuit 114 may output frequency error signal 155 to loop filter circuit 116.

Loop filter circuit 116 may process phase error signal 150 and frequency error signal 155 to generate control voltage signal 160 which loop filter circuit 116 may output to fractional-N PLL 120. For example, loop filter circuit 116 may filter phase error signal 150, frequency error signal 155, or both to remove noise from the signals and improve the stability of the signals. Loop filter circuit 116 may be any suitable type of filter such as, but not limited to, a passive resistor-capacitor filter, an active filter, or a digital filter.

Fractional-N PLL 120 may be a type of PLL that generates output frequencies by dividing oscillator signal 165 from oscillator 130 by a non-integer value made up of an integer component and a fractional component. Fractional-N PLL 120 may apply control voltage signal 160 to oscillator signal 165 to adjust the frequency and phase of oscillator signal 165 to reduce the phase and frequency differences between input clock signal 140 and feedback signal 145. Fractional-N PLL 120 may adjust the frequency and phase of output clock signal 170 until the frequency and phase of output clock signal 170 matches the frequency and phase of input clock signal 140. Fractional-N PLL 120 may also generate lock signal 175. Lock signal 175 may indicate when the frequency and phase of output clock signal 170 matches the frequency and phase of input clock signal 140.

Phase error signal 150 and frequency error signal 155 may also be output to components external to system 100 at error signal output 180. Phase error signal 150 and frequency error signal 155 may be used to indicate to SyncE controllers that the output of Fractional-N PLL 120 is in sync with the overall system of which system 100 is a part. Phase error signal 150 and frequency error signal 155 may also provide an indication when the overall system is falling out of sync. This may be one, among others, indication that may be used by a SyncE controller to put the overall system into holdover mode.

Fractional-N PLL 120 may include presets for integer and fractional values to enable fractional-N PLL 120 to use the preset values to maintain output clock signal 170 in the event that input clock signal 140 is lost. The preset integer and fractional values may be determined by averaging a digital phase locked loop output frequency.

When input clock signal 140 is lost, phase error signal 150 and frequency error signal 155 may change states. The state change of phase error signal 150 and frequency error signal 155 may direct a SyncE controller in the overall system of which system 100 is a part may go into holdover mode. a recovered clock signal of a serializer/deserializer (SerDes) transmitter phase locked loop (TxPLL) clock may be used as input clock signal 140 to DPLL 110. The SerDes TxPLL clock signal may be divided down and may be provided in the feedback path (e.g., feedback signal 145) of DPLL 110. DPLL 110 may provide a low-pass frequency filter (at loop filter circuit 116) for the recovered clock and provide updates to the integer and fractional values of the SerDes TxPLL clock signal. The integer and fractional values may be loaded as presets to fractional-N PLL 120.

System 100 may perform link loss monitoring by implementing a frequency change monitor to monitor input clock signal 140 with respect to a stable local clock. For example, a SyncE controller in the overall system of which system 100 is a part may monitor phase error signal 150 and frequency error signal 155 at error signal output 180. When the state of phase error signal 150 and frequency error signal 155 changes, the SyncE controller may determine that the link has been lost. The SyncE controller may check the frequency of input clock signal 140 at fixed intervals and may determine the stability of input clock signal 140. If a deviation in the frequency of input clock signal 140 exceeds a predetermined limit, the SyncE controller may generate a link loss signal. The link loss signal may trigger fractional-N PLL 120 to use the preset integer and fractional values determined by averaging a digital phase locked loop output frequency.

To calculate the preset integer and fractional values, system 100 may average a digital phase locked loop output frequency on a rolling basis using a moving window approach of sampling and reading the DPLL outputs (e.g., control voltage signal 160) at regular intervals to accumulate a predetermined number of samples to use to perform the averaging calculations. For example, system 100 may sample control voltage signal 160 at 11.4 milliseconds intervals to accumulate up to 64 samples. In examples with DPLL 110 having a higher operating frequency, system 100 may accumulate more samples while in examples with DPLL 110 having a lower operating frequency, system 100 may accumulate fewer samples. System 100 may read the fractional component of control voltage signal 160 and may calculate the integer component of control voltage signal 160. For example, the system 100 may execute the averaging function on the jitter attenuated adjusted frequency values from DPLL 110. System 100 may average the accumulated sampled values to calculate the integer and fractional components of control voltage signal 160. The integer and fractional components of control voltage signal 160 may be loaded as presets to fractional-N PLL 120.

When the frequency change monitor detects a link loss and generates a link loss signal, the averaging algorithm may load fractional-N PLL 120 with the preset fractional and integer values to enable fractional-N PLL 120 to use the previously loaded integer and frequency preset values to maintain output clock signal 170 at a stable value.

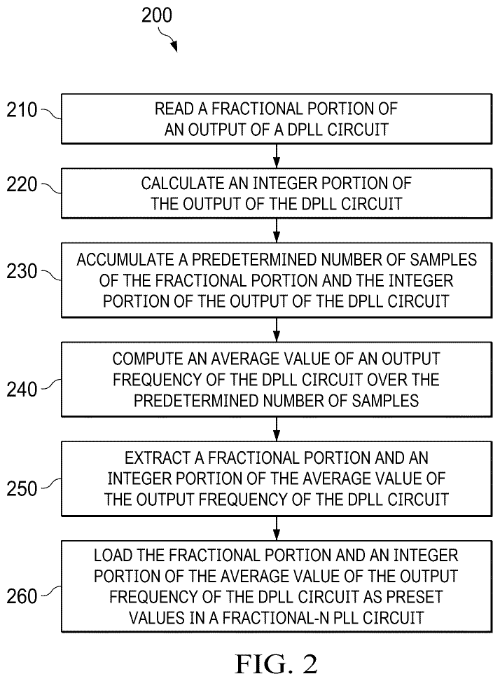

FIG. 2 illustrates a method for averaging a digital phase locked loop output frequency to calculate a preset value for use in the event of a link loss, according to examples of the present disclosure. Method 200 may be implemented by a control circuit using a central processing unit (CPU), a general purpose processor, a specific purpose processor, a microcontroller, a programmable logic controller (PLC), a digital signal processor (DSP), an application specific integrated circuit (ASIC), a field-programmable gate array (FPGA) or other programmable logic device, discrete gate or transistor logic, discrete hardware components, other programmable device, or any combination thereof designed to perform the functions disclosed herein, in combination with a processor, or any other system operable to implement method 200. For example, method 200 may be implemented by a system including a non-transitory memory including machine-readable instructions that, when executed, cause the processor to perform the steps of method 200. Although examples have been described above, other variations and examples may be made from this disclosure without departing from the spirit and scope of these disclosed examples.

Method 200 may begin at block 210 where a control circuit may read a fractional portion of an output of the DPLL circuit. The fractional portion of the output of the DPLL circuit may be control voltage signal 160 from DPLL 110 shown in FIG. 1.

At block 220, the control circuit may calculate an integer portion of the output of the DPLL circuit. When the nominal feedback divider value is an integer, then if the fractional value is greater that ½, it is assumed the integer value may be the nominal value minus 1. Otherwise, it is assumed to be the nominal value.

At block 230, the control circuit may accumulate a predetermined number of samples of the fractional portion and the integer portion of the output of the DPLL circuit. The samples may be accumulated on a rolling basis using a moving window approach of sampling and reading the DPLL outputs (e.g., control voltage signal 160 shown in FIG. 1) at regular intervals. For example, samples may be recorded at 11.4 milliseconds intervals to accumulate up to 64 samples. In examples with a DPLL circuit having a higher operating frequency, more samples may be accumulated while in examples with a DPLL circuit having a lower operating frequency, fewer samples may be accumulated.

A given sample may be calculated using the following formula

$$SUM = ( INT\_PD \_OUT * {2}^{24} ) + FRAC\_PD \_OUT$$

where FRACT_PD_OUT is the fractional portion of the output of the DPLL circuit read at block 210, INT_PD_OUT is the integer portion of the output of the DPLL circuit calculated at block 220, and SAMPLE is the given sample.

At block 240, the control circuit may compute an average value of an output frequency of the DPLL circuit over the predetermined number of samples.

At block 250, the control circuit may extract a fractional portion and an integer portion of the average value of the output frequency of the DPLL circuit.

At block 260, the control circuit may load the fractional portion and an integer portion of the average value of the output frequency of the DPLL circuit as preset values in a fractional-N PLL circuit (e.g., fractional-N PLL 120 shown in FIG. 1). The preset values may then be used by the fractional-N PLL circuit to maintain an output clock signal at a stable value in the event of a link loss.

Although FIG. 2 discloses a particular number of operations related to method 200, method 200 may be executed with greater or fewer operations than those depicted in FIG. 2. In addition, although FIG. 2 discloses a certain order of operations to be taken with respect to method 200, the operations comprising method 200 may be completed in any suitable order.

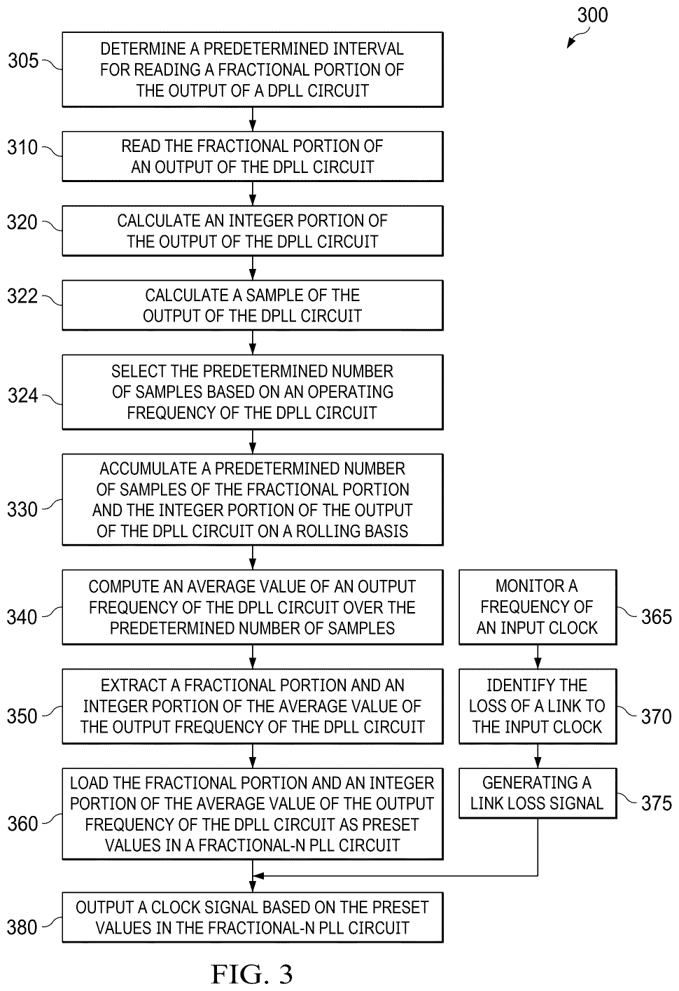

FIG. 3 illustrates a more detailed method for averaging a digital phase locked loop output frequency to calculate a preset value for use in the event of a link loss, according to examples of the present disclosure. Method 300 may be implemented by a control circuit using a CPU, a general purpose processor, a specific purpose processor, a microcontroller, a PLC, a DSP, an ASIC, an FPGA or other programmable logic device, discrete gate or transistor logic, discrete hardware components, other programmable device, or any combination thereof designed to perform the functions disclosed herein, in combination with a processor, or any other system operable to implement method 300. For example, method 300 may be implemented by a system including a non-transitory memory including machine-readable instructions that, when executed, cause the processor to perform the steps of method 300. Although examples have been described above, other variations and examples may be made from this disclosure without departing from the spirit and scope of these disclosed examples.

Method 300 may begin at block 305, where the control circuit may determine a predetermined interval for reading a fractional portion of the output of the DPLL circuit. The fractional portion of the output of the DPLL circuit may be control voltage signal 160 from DPLL 110 shown in FIG. 1. The predetermined interval may be based on the operating frequency of the DPLL circuit. For example, the predetermined interval may be shorter for a DPLL circuit having a higher operating frequency and may be longer for a DPLL circuit having a lower operating frequency. For example, the predetermined interval may be 11.4 milliseconds.

At block 310, the control circuit may read the fractional portion of an output of the DPLL circuit at the predetermined interval determined at block 305.

At block 320, the control circuit may calculate an integer portion of the output of the DPLL circuit. When the nominal feedback divider value is an integer, then if the fractional value is greater that ½, it is assumed the integer value may be the nominal value minus 1. Otherwise, it is assumed to be the nominal value.

At block 322, the control circuit may calculate a sample of the output of the DPLL circuit. The sum may be calculated using the following formula:

$$SUM = ( INT\_PD \_OUT * {2}^{24} ) + FRAC\_PD \_OUT$$

where FRACT_PD_OUT is the fractional portion of the output of the DPLL circuit read at block 210, INT_PD_OUT is the integer portion of the output of the DPLL circuit calculated at block 220, and SAMPLE is the given sample.

At block 324, the control circuit may select a predetermined number of samples. The predetermined number of samples may be based on an operating frequency of the DPLL circuit. For example, samples may be recorded at 11.4 milliseconds intervals to accumulate up to 64 samples. In examples with a DPLL circuit having a higher operating frequency, more samples may be accumulated while in examples with a DPLL circuit having a lower operating frequency, fewer samples may be accumulated.

At block 330, the control circuit may accumulate the predetermined number of samples of the fractional portion and the integer portion of the output of the DPLL circuit. The predetermined number of samples (selected at block 324) may be accumulated on a rolling basis using a moving window approach of sampling and reading the outputs of the DPLL circuit (e.g., control voltage signal 160 shown in FIG. 1) at regular intervals. For example, if the predetermined number of samples is 64, when the sixty-fifth sample is calculated, the first sample may be discarded such that the most recent 64 samples are included in the accumulation.

At block 340, the control circuit may compute an average value of an output frequency of the DPLL circuit over the predetermined number of samples. The average value of the output frequency of the DPLL circuit may be computed using a sample of the output of the DPLL circuit calculated at block 322.

At block 350, the control circuit may extract a fractional portion and an integer portion of the average value of the output frequency of the DPLL circuit.

At block 360, the control circuit may load the fractional portion and an integer portion of the average value of the output frequency of the DPLL circuit as preset values in a fractional-N PLL circuit (e.g., fractional-N PLL 120 shown in FIG. 1). The preset values may then be used by the fractional-N PLL circuit to maintain an output clock signal at a stable value in the event of a link loss.

At block 365, the control circuit may monitor a frequency of an input clock signal, such as input clock signal 140 shown in FIG. 1. The input clock signal may be monitored at fixed intervals to determine the stability of the input clock signal.

At block 370, the control circuit may identify the loss of a link to the input clock signal (monitored at block 365). If a deviation in the frequency of the input clock signal exceeds a predetermined limit, a loss of the link to the input clock signal may be identified.

At block 375, the control circuit may generate a link loss signal. The link loss signal may trigger the fractional-N PLL circuit to use the preset integer and fractional values (loaded at block 360) to calculate at output clock signal.

At block 380, the control circuit may output an output clock signal calculated based on the present values (loaded at block 360) from the fractional-N PLL circuit. The output clock signal may be used to achieve the short-and long-term holdover specifications of the SyncE standard (G.8262).

Although FIG. 3 discloses a particular number of operations related to method 300, method 300 may be executed with greater or fewer operations than those depicted in FIG. 3. In addition, although FIG. 3 discloses a certain order of operations to be taken with respect to method 300, the operations comprising method 300 may be completed in any suitable order.

Although examples have been described above, other variations and examples may be made from this disclosure without departing from the spirit and scope of these disclosed examples.

1. A method, comprising:
reading a fractional portion of an output of a digital phase locked loop (DPLL);
calculating an integer portion of the output of the DPLL;
accumulating a predetermined number of samples of the fractional portion and the integer portion of the output of the DPLL;
computing an average value of an output frequency of the DPLL over the predetermined number of samples;
extracting a fractional portion and an integer portion of the average value of the output frequency of the DPLL; and
loading the fractional portion and the integer portion of the average value of the output frequency of the DPLL as preset values in a fractional-N phase locked loop (PLL).

2. The method of claim 1, comprising:
calculating a sample of the output of the DPLL; and
computing the average value of the output frequency of the DPLL using the sample the output of the DPLL.

3. The method of claim 1, wherein the predetermined number of samples is based on an operating frequency of the DPLL.

4. The method of claim 1, comprising:
monitoring a frequency of an input clock;
identifying a loss of a link to the input clock; and
generating a link loss signal.

5. The method of claim 1, comprising outputting a clock signal based on the preset values in the fractional-N PLL.

6. The method of claim 1, comprising reading the fractional portion of the output of the DPLL at a predetermined interval.

7. The method of claim 1, wherein the predetermined number of samples is accumulated on a rolling basis.

8. An apparatus, comprising:
a digital phase locked loop (DPLL) circuit;
a fractional-N phase locked loop (PLL) circuit; and
a control circuit to:
read a fractional portion of an output of the DPLL circuit;
calculate an integer portion of the output of the DPLL circuit;
accumulate a predetermined number of samples of the fractional portion and the integer portion of the output of the DPLL circuit;
compute an average value of an output frequency of the DPLL circuit over the predetermined number of samples;
extract a fractional portion and an integer portion of the average value of the output frequency of the DPLL circuit; and
load the fractional portion and the integer portion of the average value of the output frequency of the DPLL circuit as preset values in the fractional-N PLL circuit.

9. The apparatus of claim 8, wherein the control circuit is to:
calculate a sample of the output of the DPLL; and
compute the average value of the output frequency of the DPLL using the sample of the output of the DPLL.

10. The apparatus of claim 8, wherein the predetermined number of samples is based on an operating frequency of the DPLL.

11. The apparatus of claim 8, wherein the control circuit is to:
monitor a frequency of an input clock;
identify a loss of a link to the input clock; and
generate a link loss signal.

12. The apparatus of claim 8, wherein the control circuit is to output a clock signal based on the preset values in the fractional-N PLL.

13. The apparatus of claim 8, wherein the control circuit is to read the fractional portion of the output of the DPLL at a predetermined interval.

14. The apparatus of claim 8, wherein the predetermined number of samples is accumulated on a rolling basis.

15. An article of manufacture comprising:
a non-transitory memory including machine-readable instructions that, when executed by a processor, cause the processor to:
read a fractional portion of an output of a digital phase locked loop (DPLL);
calculate an integer portion of the output of the DPLL;
accumulate a predetermined number of samples of the fractional portion and the integer portion of the output of the DPLL;
compute an average value of an output frequency of the DPLL over the predetermined number of samples;
extract a fractional portion and an integer portion of the average value of the output frequency of the DPLL; and
load the fractional portion and the integer portion of the average value of the output frequency of the DPLL as preset values in a fractional-N phase locked loop (PLL).

16. The article of manufacture of claim 15, wherein the machine-readable instructions further cause the processor to:
calculate a sample of the output of the DPLL; and
compute the average value of the output frequency of the PLL using the sample of the output of the DPLL.

17. The article of manufacture of claim 15, wherein the predetermined number of samples is based on an operating frequency of the DPLL.

18. The article of manufacture of claim 15, wherein the machine-readable instructions further cause the processor to:
monitor a frequency of an input clock;
identify a loss of a link to the input clock; and
generate a link loss signal.

19. The article of manufacture of claim 15, wherein the machine-readable instructions further cause the processor to output a clock signal based on the preset values in the fractional-N PLL.

20. The article of manufacture of claim 15, wherein the machine-readable instructions further cause the processor to read the fractional portion of the output of the DPLL at a predetermined interval.
